(19) United States
(12) Patent Application Publication
(10) Pub. No.: US 2009/0243729 A1
(43) Pub. Date: Oct. 1, 2009

(54) CONTROLLING OVERLOAD OF A TRANSIMPEDANCE AMPLIFIER IN AN OPTICAL TRANSCEIVER

(76) Inventors: Miaobin Gao, Saratoga, CA (US); Ryan Huang, Taipei (TW); Chien-Chang Liu, Sunnyvale, CA (US)

Correspondence Address: COOL PATENT, P.C.;c/o CPA Global, P.O. BOX 52050, MINNEAPOLIS, MN, 55402, US

(21) Appl. No.: 12/059,927

(22) Filed: Mar. 31, 2008

(51) Int. Cl. H03F 3/04

(52) U.S. Cl. 330/296

(57) ABSTRACT

Briefly, in accordance with one or more embodiments, a transimpedance amplifier of an optical transceiver or the like has a feedback element in a feedback arrangement and is capable of receiving an electrical current from an optical-to-electrical converter to generate an output voltage in response to the electrical current. A control circuit coupled to the feedback element is capable of providing a control signal to control a bias current of the transimpedance amplifier to maintain DC current flowing through the feedback element at or near zero by changing the bias current in response to the control circuit detecting a non-zero DC current flowing through the feedback element.

### BACKGROUND

Transimpedance amplifiers (TIA) are widely used in the receiver side of fiber optical transceiver modules. In such transceiver modules, the positivie-instrinsic-negative (PIN) photo detector detects the optical light signal strength and converts the optical signal into an electrical current input signal. An amplifier in a negative feedback arrangement converts the current input signal into a voltage to provide transimpedance amplification. Sometimes several stages of amplifiers are utilized to provide final output voltage. When the input signal is too strong, the generated current signal may be too large which pushes the voltage at the output node to be too low, thereby causing the amplifier go into saturation. As a result, the transimpedance amplifier may not operate properly anymore, and the signal could be distorted. Such a situation is referred to as overload.

### DESCRIPTION OF THE DRAWING FIGURES

Claimed subject matter is particularly pointed out and distinctly claimed in the concluding portion of the specification. However, such subject matter may be understood by reference to the following detailed description when read with the accompanying drawings in which:

FIG. 1 is a block diagram of an optical transceiver in accordance with one or more embodiments;

FIG. 2 is a plot of a typical current signal generated by a PIN diode and a resulting output voltage waveform in a transimpedance amplifier in accordance with one or more embodiments;

FIG. 3 is a diagram of a control circuit capable of addressing overload in a transimpedance amplifier in accordance with one or more embodiments; and

FIG. 4 is a diagram of the output voltage wave form in a transimpedance amplifier as a result of the control circuit of FIG. 3 in accordance with one or more embodiments.

It will be appreciated that for simplicity and/or clarity of illustration, elements illustrated in the figures have not necessarily been drawn to scale. For example, the dimensions of some of the elements may be exaggerated relative to other elements for clarity. Further, if considered appropriate, reference numerals have been repeated among the figures to indicate corresponding and/or analogous elements.

### DETAILED DESCRIPTION

In the following detailed description, numerous specific details are set forth to provide a thorough understanding of claimed subject matter. However, it will be understood by those skilled in the art that claimed subject matter may be practiced without these specific details. In other instances, well-known methods, procedures, components and/or circuits have not been described in detail.

In the following description and/or claims, the terms coupled and/or connected, along with their derivatives, may be used. In particular embodiments, connected may be used to indicate that two or more elements are in direct physical and/or electrical contact with each other. Coupled may mean that two or more elements are in direct physical and/or electrical contact. However, coupled may also mean that two or more elements may not be in direct contact with each other, but yet may still cooperate and/or interact with each other. For example, “coupled” may mean that two or more elements do not contact each other but are indirectly joined together via another element or intermediate elements. Finally, the terms “on,” “overlying,” and “over” may be used in the following description and claims. “On,” “overlying,” and “over” may be used to indicate that two or more elements are in direct physical contact with each other. However, “over” may also mean that two or more elements are not in direct contact with each other. For example, “over” may mean that one element is above another element but not contact each other and may have another element or elements in between the two elements. Furthermore, the term “and/or” may mean “and”, it may mean “or”, it may mean “exclusive-or”, it may mean “one”, it may mean “some, but not all”, it may mean “neither”, and/or it may mean “both”, although the scope of claimed subject matter is not limited in this respect. In the following description and/or claims, the terms “comprise” and “include,” along with their derivatives, may be used and are intended as synonyms for each other.

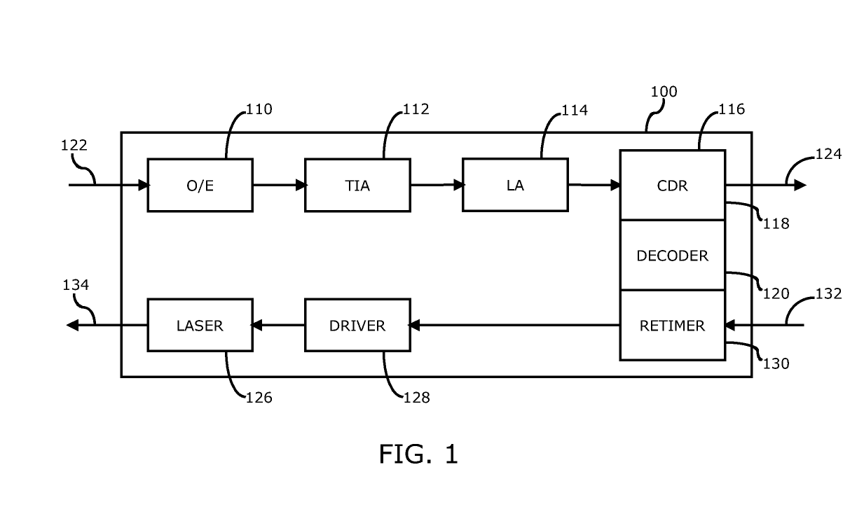

Referring now to FIG. 1, a block diagram of an optical transceiver in accordance with one or more embodiments will be discussed. In higher speed optical communication systems, information signals propagate over various distances along transmission medium 122 which may comprise, for example, optical fiber. These signals are amplified during propagation by optical amplifiers disposed along the transmission medium 122 via optical transceiver 100. In some embodiments, transceiver 100 optionally may comprise a receiver or a transmitter, or a combination thereof, and the scope of the claimed subject matter is not limited in this respect. The power levels associated with such transmitted signals may vary significantly due to a number of effects. The variations in signal power effect whether or not a particular signal is recognized by the receiver.

In one or more embodiments, transceiver 100 may be capable of receiving an optical signal from an optical transmission medium 122 such as an optical fiber or the like, and may comprise on a receive side thereof an optical-to-electrical (O/E) converter 110 which may comprise, for example, a photodetector or the like; a transimpedance amplifier (TIA) 112; a limiting amplifier (LA) 114; and a clock data recovery module 116. Clock data recovery module 116 may include a clock data and recovery (CDR) circuit 118 coupled to a decoder 120 to provide an electrical output 124 representative of the optical signal received from transmission medium 122. On a transmit side, transceiver 100 may comprise a laser 126; a laser driver circuit 128; and retimer circuit and/or encoder 130. Retimer circuit 130 receives a signal in electrical form from input 132 and provides these signals to laser driver 128 which provides current variations proportional to the received signal with which laser 126 is driven. Laser 126 then generates optical signals proportional to the received current levels for transmission over an optical transmission medium 134 which may comprise, for example, an optical fiber or the like. Transceiver 100 as shown in FIG. 1 is merely one embodiment of an optical transceiver that may include transimpedance amplifier (TIA) 112, however the scope of the claimed subject matter is not limited in this respect.

In one or more embodiments, the receive side of transceiver 100 receives optical information signals propagating along transmission medium 122 and outputs an electrical equivalent via output 124. The optical information signals are incident on O/E converter 110 where optical energy is converted to an electrical current proportional to the received optical signals. The expression “information signals,” as used herein, refers to a signal which has been coded with information. These signals are amplified during propagation by optical amplifiers disposed along the transmission medium 122 and are incident on O/E 130 which may be arranged to detect an individual wavelength and/or a range of optical wavelengths. The electrical signals generated by the photodetector of O/E converter 110 may be relatively weak so they may be converted to a voltage equivalent, as well as being squaring-off as digital pulses, regenerating clock signals, and/or noise filtering induced by transmission and dark noise generated by the photodetector of O/E converter 110. The current signal generated by photodetector of O/E converter 110 may be converted into a corresponding voltage for further processing. This conversion may accomplished by TIA 112 which typically may be characterized by a higher transimpedance on the front end and a lower impedance on the back end. TIA 112 provides higher transimpedance with lower noise amplification. Because the current signal received by TIA 112 from the photodetector of O/E converter 110 may be relatively small, TIA 112 may also function as a preamplifier to provide an output signal having an amplitude ranging from about a few millivolts to a about a few hundred millivolts. In optical communications systems, the average power of the received optical signals may vary by orders of magnitude depending on span losses, fiber nonlinearities, and so on. Thus, TIA 112 may be arranged to operate over a wider dynamic range of input currents received from the photodetector of O/E 112.

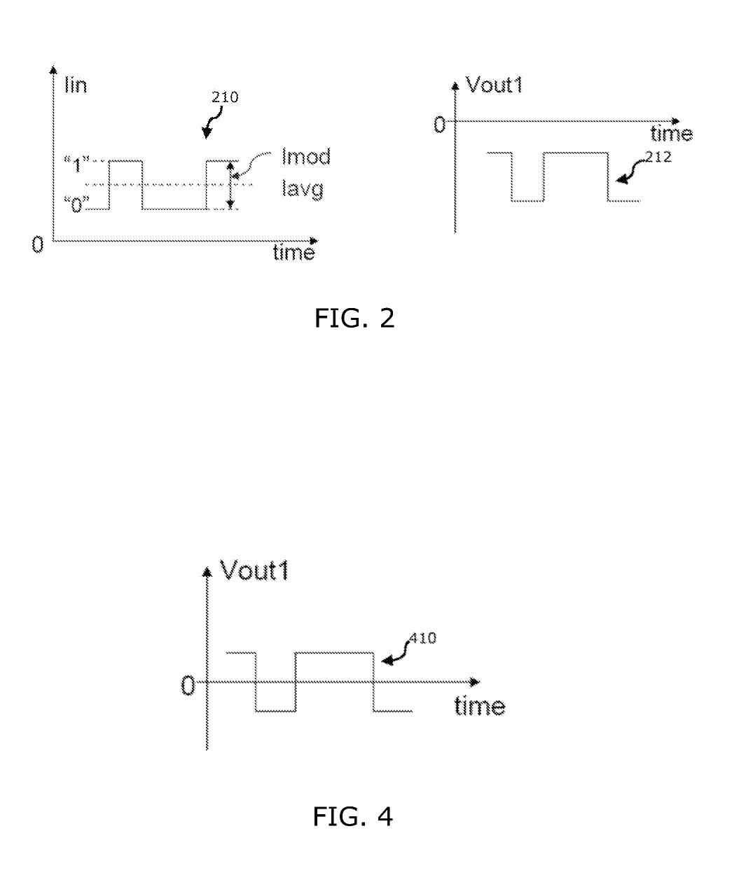

Limiting amplifier (LA) 114 may functions to produce a consistent waveform in response to an input received from TIA 114. Because the input signal received by LA 114 from TIA 110 may still be relatively small, LA 114 may provide a relatively higher gain factor to generate higher output signal levels. Such gain typically may be provided via multiple amplification stages in order to achieve higher stability at higher bandwidths than would otherwise be achieved with a single higher gain amplification stage. In other words, LA 114 is capable of increasing the voltage gain of the signals received from TIA 112 to a signal level suitable for CDR circuit 118. CDR circuit 118 is capable of recovering both the data and/or the clock signal embedded in the input data stream received by the photodetector of O/E converter 110. The input and output waveforms received and generated by transimpedance amplifier 112 are shown in and described with respect to FIG. 2, below.

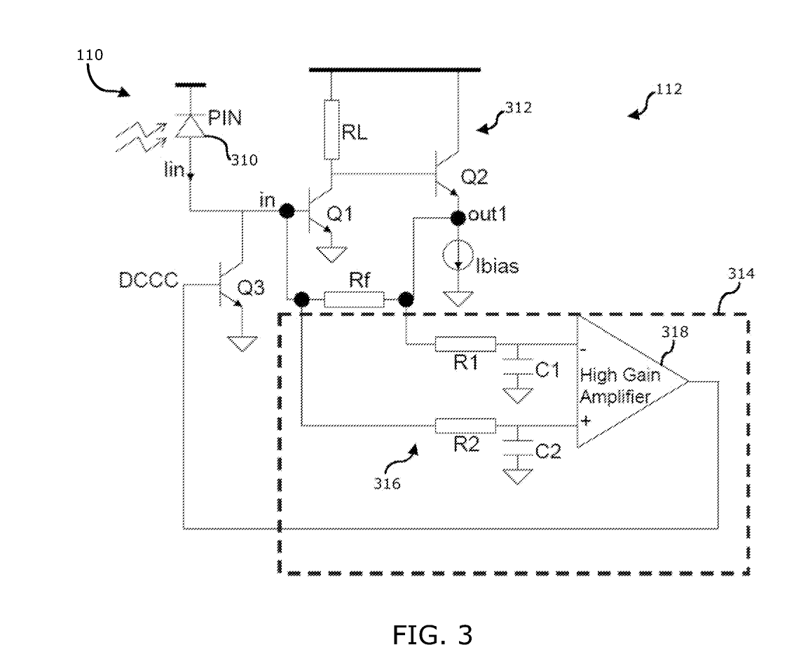

Referring now FIG. 2, a plot of a typical current signal generated by a PIN diode and a resulting output voltage waveform in a transimpedance amplifier in accordance with one or more embodiments will be discussed. As shown in FIG. 2, plot 210 represents a typical current signal generated by a PIN diode of O/E converter 110 that is provided as an input to TIA 112. The plots of FIG. 2 are discussed with respect to the circuit components of transimpedance amplifier 112 as shown in FIG. 3, below. The lower signal level corresponds to logic level “0”, and the higher signal level corresponds to logic level “1”. The average signal power may be referred to as the average current (Iavg), and the signal swing amplitude may be referred to as the modulation current (Imod). Normally, when the input signal is at logic level “0”, the minimum current is greater than about zero milliamperes. Due to the higher gain of a first amplifier 312 of TIA 112 comprising transistor Q1 and transistor Q2 as shown in FIG. 3, and the feedback configuration of resistor Rf, the majority of the input current (Iin) flows through resistor Rf, thereby generating an voltage waveform at output node “out1” represented by plot 212. When the input signal is too strong, both the average current Iavg and/or the modulation current Imod likewise could be too large, thereby pushing the output voltage at node “out1” to bee too low. Such a situation may cause amplifier 312, which may comprise a first amplification stage of TIA 112, to go into saturation, and as a result TIA 112 may no longer be operating properly, and the output signal at node “out1” could be distorted, meaning TIA 112 is in overload. This overload condition is capable of being addressed by control circuit 314 as shown in and described with respect to FIG. 3, below.

Referring now to FIG. 3, a diagram of a control circuit capable of addressing overload in a transimpedance amplifier in accordance with one or more embodiments will be discussed. To address overload in transimpedance amplifier 112, control circuit 314 may be coupled across the feedback resistor Rf of amplifier 312. In one or more embodiments, control circuit 314 operates as negative feedback control for amplifier 312 and may comprise a low pass filter 316 arranged to tap both ends of feedback resistor Rf as an input to control circuit 314. In one or more embodiments, low pass filter 316 comprises resistor R1, capacitor C1, resistor R2, and capacitor C2 to filter out higher frequency components. The signal across feedback resistor Rf is low pass filtered and provided to the differential inputs of high gain amplifier 318, which may be a DC voltage, or nearly a DC voltage. The output of high gain amplifier 318 is provided as an input signal to the base electrode of transistor Q3 to implement a DC current control circuit (DCCC) to control the bias current (Ibias) of amplifier 312. It should be noted that although the transistors of TIA 112 are shown in FIG. 3 as bipolar transistors, the transistors alternatively may comprise other types of devices such as metal oxide field effect transistors (MOSFETs), and the scope of the claimed subject matter is not limited in this respect.

In one or more embodiments, when the signal across feedback resistor Rf is sufficiently high and thus the gain of the feedback loop of amplifier 312 is sufficiently high, a control signal is provided by control circuit 314 via transistor Q3 to cause transistor Q3 to leak away all, or nearly all, of the DC component of the input current Iin, and the DC voltage level at node “in” and node “out1” will be equal, or nearly equal. The resulting output voltage waveform at node “out1” controlled by control circuit 314 is shown in and described with respect to FIG. 4, below.

Referring now FIG. 4, a diagram of the output voltage wave form in a transimpedance amplifier as a result of the control circuit of FIG. 3 in accordance with one or more embodiments will be discussed. In one or more embodiments, the output voltage waveform of plot 210 of FIG. 2 is controlled by control circuit 314 to have a resulting output waveform of plot 410 of FIG. 4. As shown in FIG. 4, plot 410 has the DC component removed, or nearly all removed, from the output voltage to have the effect of shifting the output voltage waveform to be symmetrical, or nearly symmetrical, about zero volts. Such a result may be accomplished by control circuit 314 by removing the DC current that may otherwise flow through feedback resistor Rf due to process, temperature, and/or supply voltage variation. Thus, any DC current flowing through feedback resistor Rf will result in a voltage drop across feedback resistor Rf which is in turn applied as a control to the differential inputs of high gain amplifier 318 which in turn provides a control signal to transistor Q3 so that transistor Q3 may change the bias current Ibias of amplifier 312 to cancel out the DC current through feedback resistor Rf in a negative feedback control loop arrangement to ensure the DC component flowing through feedback resistor Rf is maintained at or near about zero milliamperes. Such an arrangement of control circuit 314 operates on the DC component of the current flowing through feedback resistor Rf, however the ac gain of amplifier 312 set by feedback resistor Rf is otherwise not affected so that amplifier 312 is still capable of amplifying the input current signal Iin at a relatively higher gain factor. Thus, in one or more embodiments, the gain of high gain amplifier 318 may be selected to be high enough so that overload feedback control provided by control circuit 314 is unaffected, or nearly unaffected, by temperature, process, and/or supply voltage variations so that the DC current flowing through feedback resistor Rf is zero or nearly zero milliamperes.

Although the claimed subject matter has been described with a certain degree of particularity, it should be recognized that elements thereof may be altered by persons skilled in the art without departing from the spirit and/or scope of claimed subject matter. It is believed that the subject matter pertaining to controlling overload of a transimpedance amplifier in an optical transceiver and/or many of its attendant utilities will be understood by the forgoing description, and it will be apparent that various changes may be made in the form, construction and/or arrangement of the components thereof without departing from the scope and/or spirit of the claimed subject matter or without sacrificing all of its material advantages, the form herein before described being merely an explanatory embodiment thereof, and/or further without providing substantial change thereto. It is the intention of the claims to encompass and/or include such changes.

1. An apparatus, comprising:
an optical-to-electrical converter capable of generating an electrical current in response to an optical signal, the electrical current being representative of information stored in the optical signal;
a transimpedance amplifier capable of receiving the electrical current from said optical-to-electrical converter to generate a single-ended output voltage from a non-differential amplifier stage in response to the electrical current, the transimpedance amplifier having a feedback element in a feedback amplifier arrangement, a first terminal of the feedback element being coupled to the singled-ended output and a second terminal of the feedback element being coupled to the input of the transimpedance amplifier; and
a control circuit comprising a first and a second input, the first input and the second input being coupled across the feedback element, the control circuit being capable of providing a control signal to control a bias current of the transimpedance amplifier to maintain DC current flowing through the feedback element at or near zero by changing the bias current in response to the control circuit detecting a non-zero DC current flowing through the feedback element.

2. An apparatus as claimed in claim 1, the feedback element comprising a resistor, a capacitor, or an inductor, or combinations thereof.

3. An apparatus as claimed in claim 1, wherein the control circuit is capable of causing a waveform of the output voltage to have little or no DC component.

4. An apparatus as claimed in claim 1, the control circuit comprising a low pass filter to filter non-DC components of the detected current flowing through the feedback element to provide a filtered version of the current flowing through the feedback element.

5. An apparatus as claimed in claim 1, the control circuit comprising a high gain amplifier capable of detecting the non-zero DC current flowing through the feedback element as a voltage drop across the feedback element and to generate the control signal in response to the voltage drop.

6. An apparatus as claimed in claim 1, further comprising a DC current control circuit capable of receiving the control signal from the control signal to adjust the bias current in response to the control signal.

7. An apparatus as claimed in claim 1, wherein the control circuit is capable of maintaining the DC current through the feedback element at or near zero without affecting the AC current gain of the transimpedance amplifier.

8. An apparatus as claimed in claim 1, wherein the control circuit is capable of maintaining the DC current through the feedback element at or near zero independently, or nearly independently, of variations in process, temperature, or supply voltage, or combinations thereof.

9. A method, comprising:
receiving an electrical current in response to an optical signal, the electrical current being representative of information stored in the optical signal;
generating a singled-ended output voltage from a non-differential amplifier stage in response to said receiving the electrical current, the output voltage being based at least in part on a gain selected with a feedback element, a first terminal of the feedback element being coupled to the singled-ended output and a second terminal of the feedback element being coupled to the input of the transimpedance amplifier; and
providing a control signal to control a bias current for said generating an output voltage to maintain DC current flowing through the feedback element at or near zero by changing the bias current in response to detecting a non-zero DC current flowing through the feedback element, the control circuit comprising a first input and a second input, and the first input and the second input being coupled across the feedback element.

10. A method as claimed in claim 9, wherein said providing a control signal causes a waveform of the output voltage to have little or no DC component.

11. A method as claimed in claim 9, further comprising low pass filtering non-DC components of the detected current flowing through the feedback element to provide a filtered version of the current flowing through the feedback element.

12. A method as claimed in claim 9, wherein detecting a non-zero DC current flowing through the feedback element comprises detecting a voltage drop across the feedback element to generate the control signal in response to the voltage drop.

13. A method as claimed in claim 9, wherein said providing a control signal to control a bias current comprises receiving the control signal to adjust the bias current in response to the control signal via a DC current control circuit.

14. A method as claimed in claim 9, wherein said providing a control signal comprises maintaining the DC current through the feedback element at or near zero without affecting an AC current gain of the.

15. An apparatus as claimed in claim 9, wherein said providing a control signal comprises maintaining the DC current through the feedback element at or near zero independently, or nearly independently, of variations in process, temperature, or supply voltage, or combinations thereof.
